(19) United States
(12) Patent Application Publication
(10) Pub. No.: US 2026/0360397 A1
(43) Pub. Date: Nov. 12, 2026

(54) SEMICONDUCTOR DEVICE AND OPERATING METHOD THEREOF

(71) Applicant: Winbond Electronics Corp., Taichung City (TW)

(72) Inventor: Jongjun Kim, San Ramon, CA (US)

(73) Assignee: Winbond Electronics Corp., Taichung City (TW)

(21) Appl. No.: 19/201,957

(22) Filed: May 8, 2025

(51) Int. Cl. G11C 5/14

(52) U.S. Cl. CPC G11C 5/147; G11C 5/148

(57) ABSTRACT

Semiconductor device and operating method thereof are provided. The semiconductor device includes a memory, a detection circuit and a power-on control circuit. The memory is configured to operate using a power voltage and stores a power-on code data. The detection circuit is coupled to the memory, and configured to, when the power voltage reaches a first voltage level during a power-on sequence, perform a power-on read operation to determine whether the power-on code data read from the memory matches a predetermined code, and generate a fail signal when the power-on code data read from the memory does not match the predetermined code. The power-on control circuit is coupled to the detection circuit, and configured to increase the first voltage level to a second voltage level responsive to the fail signal. The detection circuit is configured to retry the power-on read operation when the power voltage reaches the second voltage level.

### BACKGROUND

### 1. Technical Field

The disclosure generally relates to a semiconductor device and an operating method, and more particular, to a semiconductor device and an operating method thereof.

### 2. Description of Related Art

A power-on sequence is critical step for almost every semiconductor device at initiation. The power-on sequence is designed to be a one-time process. In other words, if the power-on sequence fails, the device may enter an error state or remain in an inactive state until the issue causing the failure is resolved. For example, in the case of flash memory, if the power-on sequence fails, it may result in the device not initializing correctly or not being recognized by the system. In such cases, it may be necessary to manually power off the device, ensure that the power supply is stable and within the specified voltage range, and then attempt the power-on sequence again.

Besides, in some semiconductor devices, e.g., flash semiconductor devices, the power-on sequence may be carried out in a low power voltage environment or the power voltage may ramp up slowly from ground, which is prone to leading to various errors due to such an unfavorable power voltage situation.

### SUMMARY

Accordingly, the disclosure is directed to a semiconductor device and an operating method to ensure proper start-up and functional integrity of the semiconductor device, which is particularly beneficial in low power semiconductor device or scenarios involving slow slew rates of power supply ramping.

The semiconductor device of the present disclosure includes a memory, a detection circuit and a power-on control circuit. The memory is configured to operate using a power voltage and stores a power-on code data. The detection circuit is coupled to the memory, and configured to, when the power voltage reaches a first voltage level during a power-on sequence, perform a power-on read operation to determine whether the power-on code data read from the memory matches a predetermined code, and generate a fail signal when the power-on code data read from the memory does not match the predetermined code. The power-on control circuit is coupled to the detection circuit, and configured to increase the first voltage level to a second voltage level in response to the fail signal. The detection circuit is configured to retry the power-on read operation when the power voltage reaches the second voltage level.

The operating method of the present disclosure is configured to control a semiconductor device. The operating method includes: receiving a power voltage and performing a power-on sequence ; when the power voltage reaches a first voltage level during the power-on sequence, performing a power-on read operation to determine whether a power-on code data read from a memory matches a predetermined code, and generating a fail signal when the power-on code data read from the memory does not match the predetermined code; increasing the first voltage level to a second voltage level in response to the fail signal; retrying the power-on read operation when the power voltage reaches the second voltage level.

### BRIEF DESCRIPTION OF THE DRAWINGS

FIG. 1 illustrates a flowchart of an operating method in accordance with some embodiments of the present disclosure.

FIG. 2 illustrates a block diagram of a semiconductor device in accordance with some embodiments of the present disclosure.

FIG. 3 illustrates a flowchart of another operating method in accordance with some embodiments of the present disclosure.

FIG. 4 illustrates an operating waveform of a semiconductor device in FIG. 2 in accordance with some embodiments of the present disclosure.

### DESCRIPTION OF THE EMBODIMENTS

Generally speaking, at initiation of the semiconductor device, in order to properly power on components of the semiconductor device, a power-on sequence including a power-on read operation is performed. However, in certain scenarios, particularly for low-power electronic devices, the power voltage provided to the semiconductor device for operation may gradually increase from ground level or may be lower than 1.2 V at the initiation of the device. Consequently, the power-on read operation may fail due to insufficient power voltage. To address this issue, the operating method described in the present disclosure can be employed to control or operate a semiconductor device for performing a power-on sequence, which facilitates the successful execution of the power-on read operation, enabling the retrieval of the power-on code data correctly. Therefore, the semiconductor device of the present disclosure can successfully read necessary data during startup, ensuring proper initialization and reliable operation.

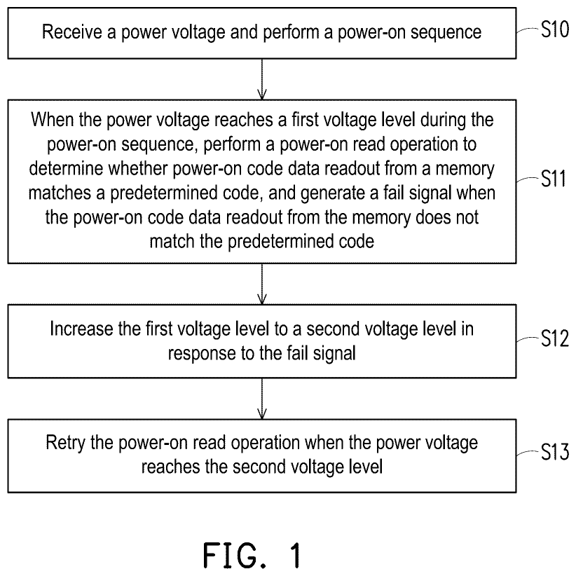

FIG. 1 illustrates a flowchart of an operating method in accordance with some embodiments of the present disclosure. The operating method includes steps S10-S12. At step S10, a semiconductor device powers up to receive a power voltage, and performs a power-on sequence. Specifically, the power voltage may be provided to the semiconductor device for supplying power to a memory configured to operate using the power voltage and store a power-on code data, so that the memory may function properly for data to be read and/or programmed.

At step S11, when the power voltage reaches a first voltage level during the power-on sequence, a power-on read (POR) operation may be performed, generating a fail signal when the POR operation fails. The POR operation includes reading the power-on code data from the memory, determining whether the power-on code data read from the memory matches a predetermined code, and generating the fail signal when the power-on code data read from the memory does not match the predetermined code. Besides, the power-on code data may carry the steps of the power-on sequence, so the power-on code data is required to be read from the memory at the initiation of the semiconductor device for executing the power-on sequence.

At step S12, the first voltage level is increased to a second voltage level in response to the fail signal. At step S13, the POR operation is retried when the power voltage reaches the second voltage level.

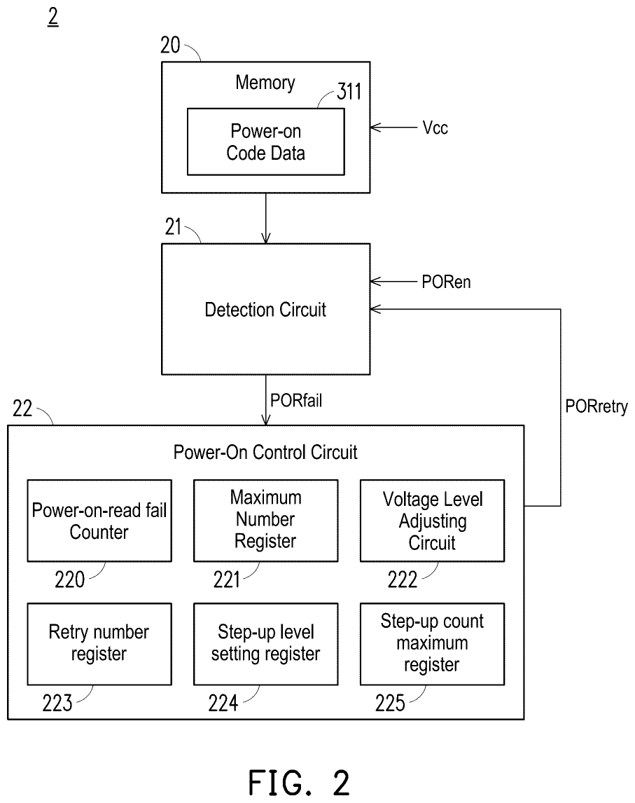

FIG. 2 illustrates a block diagram of a semiconductor device 2 in accordance with some embodiments of the present disclosure. Specifically, the operating method in FIG. 1 can be performed by the semiconductor device 2 to properly perform the power-on sequence. The semiconductor device 2 includes a memory 20, a detection circuit 21, and a power-on control circuit 22.

In the present embodiment, the memory 20 is configured to receive a power voltage Vcc for operation, and store the power-on code data 311. The memory 20 may include a plurality of memory cells (not illustrated) arranged in rows and columns as a memory array. Each memory cell may be a non-volatile memory (NVM) cell so that each NVM cell may retain its stored data even when the power is down. Examples of the NVM cell includes, for example but not limited to, a read-only memory (ROM), a programmable read-only memory (PROM), an electrically alterable read only memory (EAROM), an erasable programmable read only memory (EPROM), an electrically erasable programmable read only memory (EEROM), a flash memory, a non-volatile random-access memory (NVRAM), a Ferroelectric RAM (FRAM), a magnetoresistive RAM (mRAM), a memristor, or the like.

The detection circuit 21 is coupled to the memory 20. During initiation of the semiconductor device 20, the detection circuit 21 is configured to perform a power-on read (POR) operation to read the power-on code data 311 from the memory 20, and verify data integrity of the power-on code. If the power-on code data 311 is verified as correct, namely the power-on code data 311 read from the memory matches the predetermined code, meaning that the previous POR operation is successful, the detection circuit 21 may inform a controller or a processor (not illustrated in FIG. 2) for performing the power-on sequence according to the power-on code data 311. If the power-on code data 311 is incorrect after verification, namely the power-on code data 311 read from the memory does not match the predetermined code, the detection circuit 21 may be configured to generate a fail signal PORfail. The power-on control circuit 22 is coupled to the detection circuit 21, and configured to increase the first voltage level to a second voltage level in response to the fail signal PORfail. The detection circuit 21 is configured to retry the POR operation when the power voltage Vcc reaches the second voltage level. In some embodiments, the power-on control circuit 22 is configured to increase the second voltage level in response to the fail signal until the power-on code data 311 read from the memory 20 matches the predetermined code or until the power voltage Vcc reaches a maximum voltage level. In some embodiments, the detection circuit 21 is configured to retry the power-on read operation in response to an auto power-on signal after the power voltage Vcc reaches the second voltage level.

In the present embodiment, the power voltage Vcc ramps up during the power-on sequence. For example, the power voltage Vcc may be at a lower voltage level during the previous POR operation, and at a higher voltage level during the retried POR operation. In the present invention, by performing the retried POR operation with the power voltage Vcc at the higher voltage level, the probability of successfully reading the power-on code data 311 from the memory 20 may be increased. In some embodiments, the POR operation may be retried until it is successful. In some embodiments, the POR operation may be retried until a maximum fail number or a maximum time length is reached.

The power-on control circuit 22 includes a power-on-read fail counter 220, a maximum fail number register 221, and a voltage level adjusting circuit 222. Details regarding the power-on-read fail counter 220, the maximum fail number register 221, and the voltage level adjusting circuit 222 will be described in the following paragraphs. Although not clearly illustrated in FIG. 2, the power-on control circuit 22 may further include a processing circuit configured to perform logical operations among the outputs of the power-on-read fail counter 220, the maximum number register 221, and the voltage level adjusting circuit 222, and communicate with the detection circuit 21 based on operation results generated by the processing circuit. In some embodiment, the processing circuit of the power-on control circuit 22 may be realized by application specific integrated circuit (ASIC), field-programmable gated array (FPGA), full-custom design circuits, or circuits realized using electronic design aided (EDA) tools, such as Verilog, VHDL, etc.

In some embodiments, the power-on control circuit 22 may further include a retry number register 223 configured to store a retry number indicating how many times of the power-on read operation has been retried, and the power-on control circuit 22 is further configured to adjust the second voltage level according to the retry number. Specifically, the power-on control circuit 22 may further include a step-up level setting register 224 configured to store a step-up level, and a step-up count maximum register 225 configured to store a step-up count maximum. The power-on control circuit 22 is configured to adjust the step-up level and the step-up count maximum according to the retry number, and increase the second voltage level according to the adjusted step-up level and the adjusted step-up count maximum.

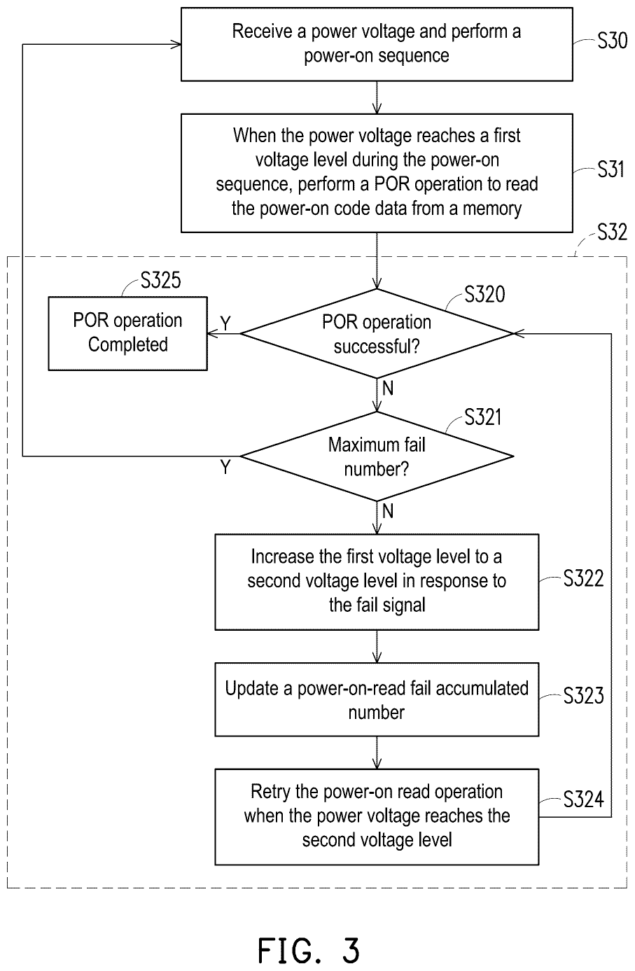

FIG. 3 illustrates a flowchart of another operating method in accordance with some embodiments of the present disclosure. Similar to the operating method in FIG. 1, the operating method in FIG. 3 may also be used to control or operate, for example, a semiconductor device 2 in FIG. 2 for performing a power-on sequence. The operating method includes steps S30-S32.

At step S30, the power voltage Vcc is provided to and received by the memory 20 for operation. At initiation of the semiconductor device 2, the power-on sequence is performed, the power voltage Vcc ramps up and may be gradually increased from ground.

At step S31, the power-on read (POR) operation is performed, by the detection circuit 21, to read the power-on code data 311 from the memory 20 when the power voltage Vcc reaches a first voltage level during the power-on sequence. Further, the detection circuit 21 is configured to evaluate the power-on code data 311 read from the memory 20 by determining whether it matches a predetermined code at a designated location. If the power-on code data 311 matches the predetermined code, the detection circuit 21 may determine that the previous POR operation was successful. Otherwise, the detection circuit 21 may determine that the previous POR operation is failed and provides the fail signal PORfail to the power-on control circuit 22.

At step S32, the power-on control circuit determines whether the detection circuit 21 retries the POR operation based on the output of the detection circuit 21. Specifically, the step S32 includes steps S320-S325. At step S320, the power-on control circuit 22 is configured to determine whether the previous POR operation fails according to the reception of the fail signal PORfail. Under the circumstance of not receiving the fail signal PORfail, it means that the previous POR operation is successful, step S325 may follow to end the POR operation, and the power-on sequence will proceed based on the obtained power-on code data 311.

If the fail signal PORfail is received, the detection circuit 21 may determine that the previous POR operation failed and proceed to step S321. At step S321, a maximum fail number of the POR operation will be evaluated to see whether the terminating condition of the POR operation is reached or not. Specifically, the power-on control circuit 22 includes a power-on-read fail counter 220 and a maximum fail number register 221. The maximum fail number register 221 is configured to store the maximum fail number. The power-on-read fail counter 220 is configured to count a power-on-read fail accumulated number indicating how many of the fail signals PORfail have been generated. The power-on control circuit 22 may be configured to compare the power-on-read fail accumulated number with the maximum fail number.

If the power-on-read fail accumulated number is less than the maximum fail number, at S322, the power-on control circuit 22 may be configured to increase the first voltage level to a second voltage level in response to the fail signal PORfail. If the power-on-read fail accumulated number is greater than or equal to the maximum fail number, step S30 may follow to restart the power-on sequence again. In some embodiments, the power-on control circuit 22 may include a voltage level adjusting circuit 222 configured to ramp up the first voltage level to the second voltage level in response to the fail signal PORfail, and inform the power-on control circuit 22 of when to retry the power-on read operation.

At step S323, the power-on-read fail counter 220 is configured to update the power-on-read fail accumulated number after the first voltage level is ramped up to the second voltage level.

Specifically, at S322, in order to obtain a higher power voltage Vcc supplied to the memory 20 during the next POR operation, the power-on control circuit 22 may setup a reference voltage level sufficiently high or an awaited time length sufficiently long as a trigger condition for performing the next POR operation.

In some embodiments, the voltage level adjusting circuit 222 may be a voltage comparator, and the voltage level adjusting circuit 222 may be configured to compare the power voltage Vcc with the second voltage level. The voltage level adjusting circuit 222 may be configured to inform the detection circuit 21 to retry the POR operation when the power voltage Vcc reaches the second voltage level, so the retried POR operation may be performed after the higher power voltage Vcc is provided to the memory 20.

In some embodiments, the voltage level adjusting circuit 222 may be a cycle counter configured to keep track of a cycle number of the semiconductor device 2 has elapsed. More specifically, the cycle number corresponds to the time length for the power voltage Vcc to ramp up, so the larger cycle time is, the longer awaited time length elapsed and the higher power voltage Vcc is supplied to the memory 20. In this embodiment, the voltage level adjusting circuit 222 may inform the power-on control circuit 22 to retry the POR operation when a predetermined number of cycles is reached. In other words, the cycle count may be used as another index for evaluating whether the power voltage Vcc is high enough to retry another POR operation.

At step S324, the power-on control circuit 22 may instruct the detection circuit 21 retrying the POR operation. In some embodiments, the power-on control circuit 22 may be configured to inform the detection circuit 21 retrying the POR operation when the higher reference voltage level (for example, the second voltage level) or the predetermined number of cycles is reached, so that the operating method will loop back to step S320 to check whether the previous POR operation was successful.

At step S325, the entire loop of retrying the POR operation will be ended when the POR operation is deemed successful, or the maximum fail number is reached.

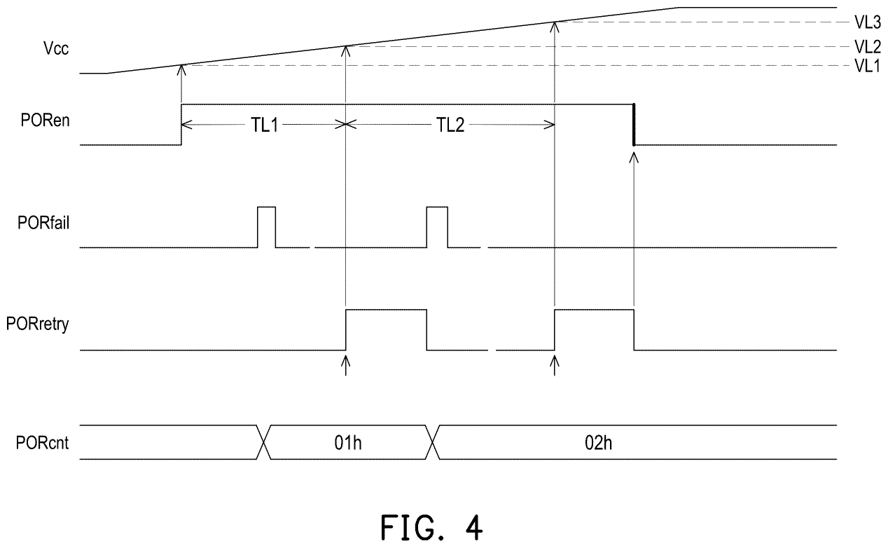

FIG. 4 illustrates an operating waveform of a semiconductor device 2 in FIG. 2 in accordance with some embodiments of the present disclosure.

As can be seen in FIGS. 2 and 4, a power voltage Vcc is provided to the memory array 20 and may be increased gradually during a power-on sequence. In some embodiments, when the power voltage Vcc reaches a first voltage level VL1, an enable signal PORen may be pulled high, enabling the detection circuit 21 to perform a first POR operation. In some embodiments, although not clearly illustrated, a startup circuit may be utilized to evaluate whether the power voltage Vcc reached the first voltage level VL1, to accordingly pull up the enable signal PORen.

After the enable signal PORen is pulled high, the detection circuit 21 may start to perform the POR operation and attempt to fetch the power-on code data 311 from the memory 20. In this embodiment, when the detection circuit 21 determines that first POR operation is failed, the detection circuit 21 may submit a fail signal PORfail to the power-on control circuit 22. In response to receiving the fail signal PORfail, the power-on control circuit 22 may update a power-on-read fail accumulated number PORcnt using the power-on-read fail counter 220. Further, the power-on control circuit 22 may be configured to evaluate whether the power-on-read fail accumulated number PORcnt is less than the maximum fail number. If the power-on-read fail accumulated number PORcnt is less than the maximum fail number, the power-on-read fail counter 220 of the power-on control circuit 22 may update the power-on-read fail accumulate number PORcnt, the voltage level adjusting circuit 222 may increase the first voltage level to a second voltage level VL2 or setup a predetermined number of cycles corresponding to a wait time length TL1 for next POR operation. When the power voltage Vcc reaches the second voltage level or the wait time length TL1 has elapsed, the power-on control circuit 22 may generate a retry signal PORretry to inform the detection circuit 21 to retry the POR operation in response to the retry signal PORretry.

Upon receiving the retry signal PORretry, the detection circuit 21 may retry the POR operation, in other words, may perform a second POR operation to attempt reading the power-on code data 311 from the memory 20. Once the detection circuit 21 determines that the second POR operation still fails and submits the fail signal PORfail, operations of the power-on control circuit 22 may be retried to increase the second voltage level VL2 to a third voltage level VL3 or setup a predetermined number of cycles corresponding to a wait time length TL2, so that the detection circuit 21 may retry the POR operation, in other words, may perform a third POR operation to attempt reading the power-on code data 311 from the memory 20 when the power voltage Vcc reaches the third voltage level VL3 or the wait time length TL2 has elapsed.

As shown in FIG. 4, the retry signal PORretry transitions from a first logic level to a second logic level when the power voltage Vcc reaches the second voltage level VL2, remains at the second logic level when the power-on read operation is retried, and transitions from the second logic level to the first logic level when the detection circuit generates the fail signal PORfail after the power-on read operation is retried. Besides, the power-on control circuit 22 is configured to generate an enable signal PORen transitioning from the first logic level to the second logic level when the power voltage Vcc reaches the first voltage level, and remaining at the second logic level until when the power-on code data 311 matches the predetermined code after the power-on read operation is retried.

According to the present embodiment, in the third POR operation, the detection circuit 21 determines that the power-on code data 311 matches a predetermined code. Therefore, the detection circuit 21 may pull low the enable signal PORen to end the POR operation, so that the power-on sequence may be continued according to the verified power-on code data 311.

In summary, the semiconductor device and the operating method may be configured to evaluate the POR operation and efficiently retry the POR operation when the previous one fails. The retried POR operation may be performed with the higher power voltage supply, gaining better chance of the successful POR operation, so that the power-on sequence may be correctly performed according to the power-on code data. Accordingly, the disclosure can ensure proper start-up and functional integrity of the semiconductor device, which is particularly beneficial in low power semiconductor device or scenarios involving slow slew rates of power supply ramping.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device, comprising:
a memory configured to operate using a power voltage and store a power-on code data;
a detection circuit, coupled to the memory, and configured to, when the power voltage reaches a first voltage level during a power-on sequence, perform a power-on read operation to determine whether the power-on code data read from the memory matches a predetermined code, and generate a fail signal when the power-on code data read from the memory does not match the predetermined code; and
a power-on control circuit, coupled to the detection circuit, and configured to increase the first voltage level to a second voltage level in response to the fail signal,
wherein the detection circuit is configured to retry the power-on read operation when the power voltage reaches the second voltage level.

2. The semiconductor device of claim 1, wherein
the power voltage ramps up during the power-on sequence, and
the power-on control circuit is configured to increase the second voltage level in response to the fail signal until the power-on code data read from the memory matches the predetermined code or until the power voltage reaches a maximum voltage level.

3. The semiconductor device of claim 1, wherein the power-on control circuit includes a retry number register configured to store a retry number indicating how many times of the power-on read operation has been retried, and the power-on control circuit is further configured to adjust the second voltage level according to the retry number.

4. The semiconductor device of claim 1, wherein the power-on control circuit includes:
a retry number register configured to store a retry number indicating how many of the power-on read operation has been retried;
a step-up level setting register configured to store a step-up level; and
a step-up count maximum register configured to store a step-up count maximum,
wherein the power-on control circuit is configured to adjust the step-up level and the step-up count maximum according to the retry number, and increase the second voltage level according to the adjusted step-up level and the adjusted step-up count maximum.

5. The semiconductor device of claim 1, wherein the detection circuit is configured to retry the power-on read operation in response to an auto power-on signal after the power voltage reaches the second voltage level.

6. The semiconductor device of claim 1, wherein the power-on control circuit is configured to generate a retry signal when the power voltage reaches the second voltage level, and the detection circuit is configured to retry the power-on read operation in response to the retry signal.

7. The semiconductor device of claim 1, wherein the power-on control circuit is configured to control the detection circuit to retry the power-on read operation until a maximum fail number is reached.

8. The semiconductor device of claim 7, wherein the power-on control circuit comprises:
a power-on-read fail counter configured to count a power-on-read fail accumulated number indicating how many of the fail signals have been generated; and
a maximum fail number register configured to store the maximum fail number,
wherein the power-on control circuit is configured to compare the power-on-read fail accumulated number with the maximum fail number to determine whether to retry the power-on read operation.

9. The semiconductor device of claim 8, wherein the power-on control circuit comprises a voltage level adjusting circuit configured to ramp up the first voltage level to the second voltage level in response to the fail signal, and inform the power-on control circuit of when to retry the power-on read operation, wherein the power-on-read fail counter is configured to update the power-on-read fail accumulated number after the first voltage level is ramped up to the second voltage level.

10. The semiconductor device of claim 9, wherein the power-on control circuit is configured to generate a retry signal after the power-on-read fail accumulated number is updated, and the detection circuit is configured to retry the power-on read operation in response to the retry signal.

11. The semiconductor device of claim 1, wherein the power-on control circuit includes a cycle counter configured to inform the detection circuit to retry the power-on read operation after a predetermined number of cycles are elapsed.

12. The semiconductor device of claim 6, wherein
the retry signal transitions from a first logic level to a second logic level when the power voltage reaches the second voltage level, remains at the second logic level when the power-on read operation is retried, and transitions from the second logic level to the first logic level when the detection circuit generates the fail signal after the power-on read operation is retried,
the power-on control circuit is configured to generate an enable signal transitioning from the first logic level to the second logic level when the power voltage reaches the first voltage level, and remaining at the second logic level until when the power-on code data read from the memory matches the predetermined code after the power-on read operation is retried.

13. An operating method of a semiconductor device, the operating method comprising:
receiving a power voltage and performing a power-on sequence;
when the power voltage reaches a first voltage level during the power-on sequence, performing a power-on read operation to determine whether a power-on code data read from a memory matches a predetermined code, and generating a fail signal when the power-on code data read from the memory does not match the predetermined code;
increasing the first voltage level to a second voltage level in response to the fail signal; and
retrying the power-on read operation when the power voltage reaches the second voltage level.

14. The operating method of claim 13, wherein
ramping up the power voltage during the power-on sequence, and
the second voltage level is increased in response to the fail signal until the power-on code data read from the memory matches the predetermined code or until the power voltage reaches a maximum voltage level.

15. The operating method of claim 13, further comprising:
storing a retry number indicating how many times of the power-on read operation has been retried in a retry number register; and
adjusting the second voltage level according to the retry number.

16. The operating method of claim 13, further comprising:
Storing a retry number indicating how many of the power-on read operation has been retried in a retry number register;
storing a step-up level in a step-up level setting register;
storing a step-up count maximum in a step-up count maximum register; and
adjusting the step-up level and the step-up count maximum according to the retry number,
wherein the second voltage level is increased according to the adjusted step-up level and the adjusted step-up count maximum.

17. The operating method of claim 13, further comprising:
retrying the power-on read operation in response to an auto power-on signal after the power voltage reaches the second voltage level.

18. The operating method of claim 13, further comprising:
generating a retry signal when the power voltage reaches the second voltage level, wherein the power-on read operation is retried in response to the retry signal.

19. The operating method of claim 13, further comprising:
retrying the power-on read operation until a maximum fail number is reached.

20. The operating method of claim 18, further comprising:
updating a power-on-read fail accumulated number indicating how many of the fail signals have been generated after the first voltage level is ramped up to the second voltage level,
wherein the retry signal is generated after the power-on-read fail accumulated number is updated.
